(19) United States
(12) Patent Application Publication
(10) Pub. No.: US 2009/0086779 A1
(43) Pub. Date: Apr. 2, 2009

(54) SEMICONDUCTOR LASER DIODE WITH REDUCED PARASITIC CAPACITANCE

(75) Inventor: Atsushi Matsumura, Yokohama-shi (JP)

Correspondence Address: VENABLE LLP, P.O. BOX 34385, WASHINGTON, DC, 20043-9998, US

(73) Assignee: SUMITOMO ELECTRIC INDUSTRIES, LTD., Osaka (JP)

(21) Appl. No.: 12/237,867

(22) Filed: Sep. 25, 2008

(30) Foreign Application Priority Data
Sep. 27, 2007 (JP) 2007-252338

(51) Int. Cl. H01S 5/00; H01L 21/02

(52) U.S. Cl. 372/45.01; 438/26; 438/39; 257/E21.002

(57) ABSTRACT

The LD of the invention provides a semiconductor stack including the current confinement region with the active mesa and the semi-insulating burying regions putting the active mesa therebeteen and the conductive region in contiguity with the current confinement region. The current confinement region and the conductive region are provided on epitaxially grown cladding layer. Two semiconductor regions, which are physically isolated to each other and each includes the semiconductor substrate, are provided on the semiconductor stack. One of regions comes in contact with one of burying regions and the active mesa, while, the other semiconductor regions comes in contact with the other of burying regions and the conductive region.

### BACKGROUND OF THE INVENTION

1. Field of the Invention

The present invention relates to a semiconductor laser diode (hereafter denoted as LD), in particular, the invention relates to an LD with reduced parasitic capacitance even when the LD is mounted in the epi-down arrangement.

2. Related Prior Art

Japanese Patent Application published as JP-2006-286809A has disclosed an LD with the semi-insulating buried hetero-structure (SI-BH). This LD provides an n-side electrode and semiconductor layers stacked on the n-electrode. The semiconductor layers include an n-type InP substrate, an n-type InP buffer layer, and an n-type InP cladding layer. On the InP cladding layer is provided with two semi-insulating InP burying layers and, between these two InP burying layers, a plurality of layers including a stress-induced MQW active layer comprising a combination of AlGaInAs/AlGaInAs with different compositions. This arrangement of the semiconductor layers is often called as the SI-BH structure. On the SI-BH structure is formed with a p-side electrode.

When such an LD with SI-BH structure is mounted on a base material in, what is called, the epi-down arrangement, in which the p-side electrode faces and comes in contact with the sub-mount to enhance the heat dissipating function of the LD, a parasitic capacitor is inherently formed. The p-side electrode in a whole portion thereof comes in contact with the sub-mount, while, the n-side electrode is formed in a whole surface of the InP substrate. Thus, between two electrodes is inherently formed with a parasitic capacitor even when the semi-insulating burying region is put between the electrodes. This parasitic capacitor restricts the high-frequency performance of the LD.

### SUMMARY OF THE INVENTION

One aspect of the present invention relates to a structure of an LD that comprises a first cladding layer, a current confinement region, a conductive region, and first and second semiconductor regions. The current confinement region on the first cladding layer includes an active mesa and first and second burying regions putting the active mesa therebetween. The conductive region on the first cladding layer is provided in contiguity with the confinement region. The first and second semiconductor regions provide respective electrodes thereon. The first semiconductor region is provided on the first burying region and the active mesa, while the second semiconductor region is provided on the second burying region and the conductive region. In the present LD, the first and second semiconductor regions are physically isolated to each other. Therefore, the current injected from the second electrode passes through the second semiconductor region, the conductive region, the first cladding layer, the active mesa, the first semiconductor region, and the first electrode on the first semiconductor region.

Two burying region of the present invention shows the semi-insulating characteristic. The present LD shows lesser parasitic capacitance even when the LD is mounted in the epi-down arrangement, because the present LD dose not provide the electrode extending in a whole surface of the substrate or that of the epitaxial layer.

Another aspect of the present invention relates to a method to produce an assembly of an LD on a sub-mount. The method comprises steps of: (a) growing a stack of semiconductor layers epitaxially on a semiconductor substrate, (b) etching said stack to form an active mesa including an active layer, (c) burying the active mesa by selectively growing a semi-insulating burying layer on both sides of the active mesa, (d) forming a conductive region by etching a portion of the burying layer and burying the etched portion of the burying layer, and (e) etching a portion of the semiconductor substrate so as to expose a surface of the burying region to form a pair of semiconductor regions that is physically isolated to each other.

The stack of semiconductor layers may include a cladding layer, a tunnel junction, a separated confinement hetero-structure layer, the active layer, and another separated confinement hetero-structure layer. The process of the invention may further include a step to mount thus formed LD on the sub-mount such that the cladding layer faces and comes in contact with the sub-mount.

### BRIEF DESCRIPTION OF DRAWINGS

FIG. 1 is a perspective view to show an LD according to an embodiment of the invention;

FIG. 2A is a cross section of the LD of the present invention, and FIG. 2B is a cross section of the conventional LD, where both LDs are mounted on the sub-mount in the epi-down arrangement;

FIGS. 3A to 3H show process steps to form the LD according to the present invention; and

FIG. 4 shows a calculated dependence of the parasitic capacitance and the 3 dB bandwidth on the width of the burying region.

### DESCRIPTION OF PREFERRED EMBODIMENTS

Next, various embodiments of the present invention will be described in detail as referring to accompanying drawings. In the description of drawings, the same elements will be referred by the same symbols or the same numerals without overlapping explanations.

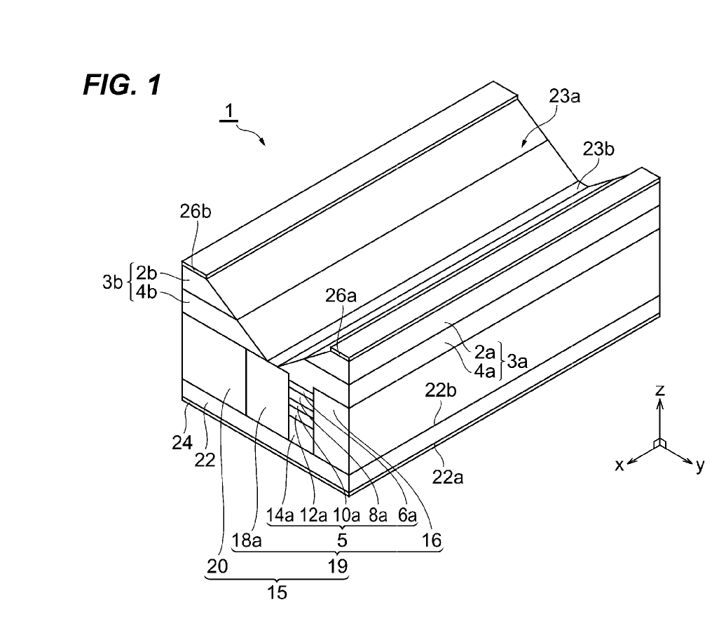

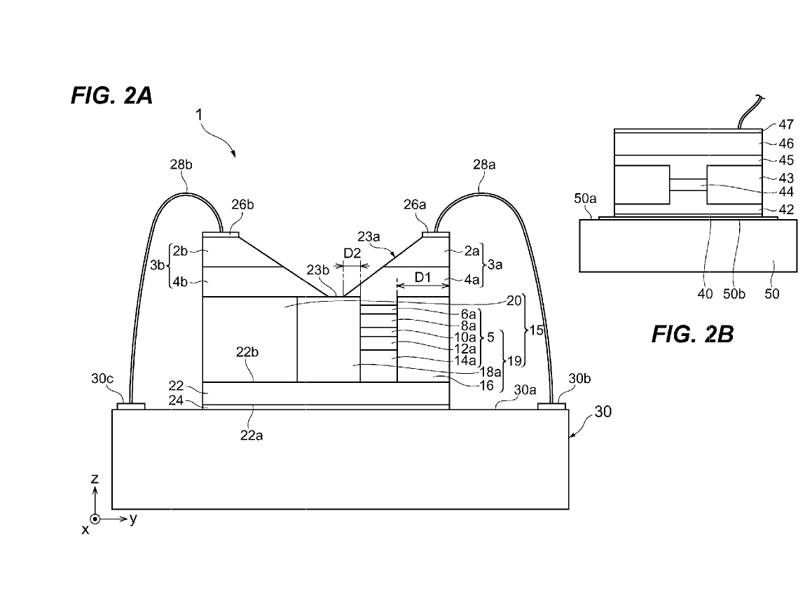

The structure of the LD according to one embodiment will be described as referring to FIGS. 1 and 2. FIG. 1 is a perspective view of the LD 1, while FIG. 2 shows a cross section of the LD 1. The LD 1 includes two semiconductor regions, 3a and 3b, a semiconductor stack 15, an InP cladding region 22, which is the first cladding region), a metal film 24, and first and second electrodes, 26a and 26b. The InP cladding region 22 is in contact with the metal film 24 at a surface 22a and in contact with the semiconductor stack 15 at another surface 22b.

The metal film 24, as illustrated in FIG. 2A, by a surface 22a thereof may be attached to a primary surface 30a of the sub-mount 30 with a solder. Thus, the LD 1 may be assembled on the sub-mount 30 in the epi-down arrangement. In this configuration, the metal film 24 may be omitted. That is, the first cladding region 22 may directly come in contact with the sub-mount 30 with a resin.

Two semiconductor regions, 3a and 3b, are provided on the semiconductor stack 15 such that two regions, 3a and 3b, are physically isolated to each other. One of the electrodes 26a is provided on one of the semiconductor regions 3a, while, the other of electrodes 26b is on the other semiconductor region 3b.

The semiconductor stack 15 includes a current confinement region 19 and the conductive region 20. The current confinement region 19, put between one of the semiconductor regions 3a and the first cladding region 22, includes an active mesa 5 and two burying regions, 16 and 18a, made of semi-insulating InP; while, the conductive region 20 is put between the other of the semiconductor regions 3b and the first cladding region 22. Thus, the first cladding region 22 arranges, in the primary surface thereof 22b along the y-direction, the first burying region 16, the active mesa 5, the second burying region 19a and the conductive region 20 in this order. The first burying region 16 has a width D1, while, the second burying region 18a has another width D2 in a portion thereof to come in contact with the first semiconductor region 3a. Between two semiconductor regions, 3a and 3b, is formed with a groove 23a, that is, two regions, 3a and 3b, each has a slope in a side facing the other regions and these two slopes form the groove 23a.

The active mesa 5 is put between two burying regions, 16 and 18a, so as to confine the current within the active mesa 5. The active mesa 5 includes a tunnel junction 6a, a separate confinement hetero-structure (hereafter denoted as SCH) layer 8a made of InGaAsP, a multi-quantum well (hereafter denoted as MQW) layer 10a made of InGaAsP, another InGaAsP SCH layer 12a, and an InP layer 14a. These layers, 6a to 14a, are stacked on the primary surface 22a of the first cladding region 22 along the z-direction.

Two burying regions may be made of InP doped with iron (Fe) to show the semi-insulating characteristic. Each width of these two burying regions, where the width means a length along the y-direction, is smaller than a width of the metal film 24. Moreover, each area of two burying regions, 16 and 18a, is narrower than that of the metal film 24. The width of the first electrode 26a is smaller than the widths of two burying regions, 16 and 18a, and the area of the first electrode 26a is narrower than areas of two burying regions, 16 and 18a.

The first semiconductor region 3a, which is a type of a mesa provided on the current confinement region 19, includes a second cladding region 4a made of InP and a first semiconductor substrate 2a made of also InP. The second cladding region 4a, provided on the first burying region 16 and the active mesa 5, in a portion thereof comes in contact with the other burying region 18a. The InP substrate 2a, provided on the InP cladding region 4a, comes in contact with the second cladding region 4a. The other semiconductor region 3b, provided on the conductive region 20, has a mesa shape and includes a third cladding region 4b made of InP and the second semiconductor substrate 2b made of also InP. The InP cladding layer 4b, provided on the conductive region 20, in a portion thereof comes in contact with the second burying region 18a. The second substrate 2b is provided on the InP cladding layer 4b.

The first substrate 2a provides the first electrode 26a thereon, while, the second substrate 2b provides the second electrode 26b thereon. An area of each electrode, 26a or 26b, is narrower than that of the metal film 24. A bonding wire 28a connects the first electrode 26a with a pad 30b on the sub-mount 30 to supply the bias current to the LD 1, while, the other bonding wire 28b connects the second electrode 26b with the other pad 30c on the substrate to supply a modulation current to the LD 1.

As described above, two semiconductor regions, 3a and 3b, are physically isolated each other by the groove 23a that extends along the x-direction. A portion of the top surface of the second burying region 18a forms a bottom 23b of the groove 23a.

Two semiconductor substrates, 2a and 2b, is an n-type InP doped within (Sn) by a concentration of around 2×10¹⁸ cm⁻³. Two cladding layers, 4a and 4b, are the n-type InP doped with silicon (Si) by a concentration of about 1×10¹⁸ cm⁻³ and have a thickness of about 500 nm. The tunnel junction 6a comprises an n⁺-type InGaAs with a thickness of about 10 nm and heavily doped with Si by a concentration of about 1×10²⁰ cm⁻³, and a p⁺-type InGaAs with a thickness of about 10 nm and heavily doped with carbon (C) by a concentration of about 1×10²⁰ cm⁻³. The SCH layer 8a is a p-type InGaAsP with a thickness of about 50 nm and a composition thereof corresponding to a band gap wavelength of λ=1.20 μm.

The MQW layer 10a made of InGaAsP shows a band gap wavelength of λ=1.10 μm, where the band gap wavelength means a wavelength where the maximum emission is obtained. The other SCH layer 12a is made of n-type InGaAsP with a thickness of about 20 nm, whose composition corresponds to a band gap wavelength of λ=1.20 μm. The InP layer 14a is an n-type layer doped with Si by a concentration of about 1×10¹⁸ cm⁻³ and has a thickness of about 500 nm. Two burying regions, 16 and 18a, are doped with iron (Fe) by a concentration of about 5×10¹⁶ cm⁻³, the conductive region 20 is an n-type InP doped with Si by a concentration of 1×10¹⁸ cm⁻³, and the InP cladding region 22 is an n-type region doped with Si by a concentration of about 1×10¹⁹ cm⁻³ and a thickness of about 500 nm.

The carriers injected in the electrodes may reach the MQW active layer 10a through the tunnel junction 6a comprised of n⁺-InGaAs and p⁺-InGaAs. These two heavily doped layers lattice-matches with the second cladding layer 4a made of InP. Accordingly, the tunnel junction 6 may convert the type of the majority carrier with relatively high efficiency.

Biasing the LD 1 so as to set the first electrode 26a in a high potential with respect to the second electrode 26b, the current flows in the active mesa 5 with the direction from the tunnel junction 6a to the InP layer 14a. When the tunnel junction 6a is provided between the first SCH layer 12a and the InP layer 14a, the current flows from the InP layer 14a to the other SCH layer 8a, when the bias is set such that the first electrode 26a is negative with respect to the other electrode 26b.

Thus, the LD 1 provides two electrodes, 26a and 26b, both on the semiconductor stack 15; that is, two electrodes, 26a and 26b, are formed in one side of the stack 15. The conventional device often provides the electrodes in two sides of the device, namely, in the top surface and the back surface of the device. FIG. 2B schematically illustrates a typical example of the conventional structure, in which an LD is mounted, in the epi-down arrangement, on a metal pad 50b provided on a top surface 50a of a sub-mount 50. The device shown in FIG. 2B provides a p-side electrode 40, a p-type cladding layer 42, a burying layer 43, an active layer 44, an n-type cladding layer 45, a substrate 46 and an n-side electrode 47. The semiconductor layers, 42 to 36, are put between two electrodes, 40 and 47. When such a device is mounted on the metal pad 50 in the epi-down arrangement, a parasitic capacitor is inevitably formed between the metal pad 50b on the sub-mount 50 and the n-side electrode 47. Moreover, not only the p-side electrode but the n-side electrode is formed so as to cover the whole surface of the device.

The LD 1 according to the present embodiment, on the other hand, because two electrodes, 26a and 26b, are formed in one side of the device, the LD 1 does not provide a parasitic capacitor, which conventional LD inevitably accompanies, between two electrodes even when the LD 1 is mounted on the sub-mount in the epi-down arrangement. Thus, the present LD 1 is able to cope with the effective heat-dissipating function and the reduced parasitic capacitance.

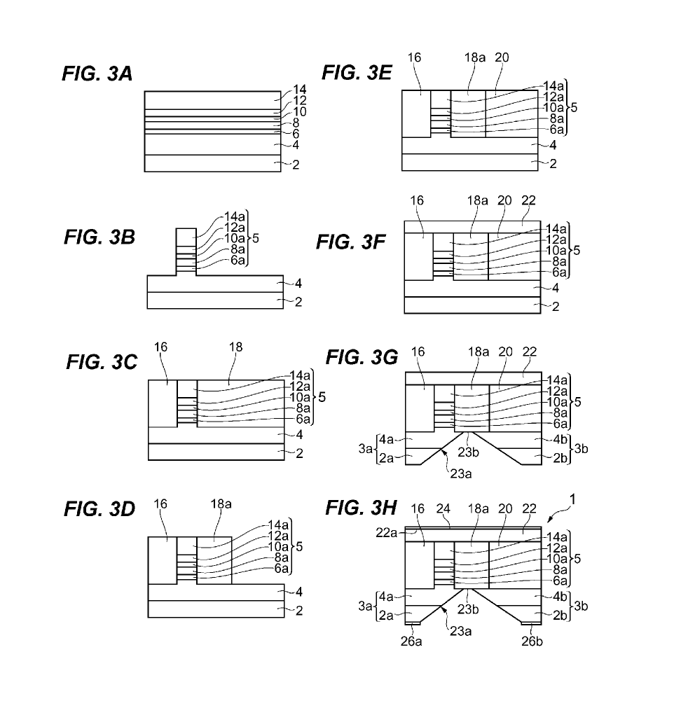

Next, a method to produce the LD 1 will be described as referring to FIGS. 3A to 3H. First, a plurality of semiconductor layers, 4 to 14, is grown on the InP substrate 2 (FIG. 3A). The grown layers include an InP cladding layer 4, a tunnel junction 6, and a first SCH layer 8 of InGaAsP, an MQW active layer 10 of InGaAsP, another SCH layer 12 of InGaAsP, and an InP layer 14.

The InP substrate 2 is made of n-type InP doped with tin (Sn) by a concentration of about 2×10¹⁸ cm⁻³. The InP cladding layer 4 is an n-type layer doped with silicon (Si) by a concentration of about 1×10¹⁸ cm⁻³ and a thickness of about 500 nm. The tunnel junction 6 comprises an n⁺-InGaAs with a thickness of about 10 nm and doped with silicon (Si) by a concentration of about 1×10²⁰ cm⁻³ and a p⁺-InGaAs with a thickness of about 10 nm and doped with carbon (C) by a concentration of about 1×10²⁰ cm⁻³. The first SCH layer 8, which is made of InGaAsP with a thickness of about 50 nm and a band gap wavelength of λ=1.20 μm, forms a separated confinement hetero-structure with respect to the MQW active layer 10. The MQW active layer 10 includes the multi-quantum well structure having barrier layers which has a band gap wavelength of λ=1.10 μm. The other SCH layer 12, having a thickness of about 20 nm and a band gap wavelength of λ=1.20 μm, also forms the separated confinement hetero-structure with respect to the MQW active layer 10. The InP layer 14 is doped with silicon (Si) by a concentration of about 1×10¹⁸ cm⁻³ and has a thickness of about 500 nm.

After the stacking of semiconductor layers described above, the process forms the active mesa 5 on the InP cladding layer 4 by an etching, FIG. 3B.

Subsequent to the etching above, the active mesa 5 is buried with burying regions, 16 and 18, by growing both regions selectively in portions etched in the foregoing step. Thus, the InP cladding layer 4 provides two burying regions, 16 and 18, and the active mesa 5 thereon. Moreover, two burying regions, 16 and 18, put the active mesa 5 therebetween as coming in contact with the active mesa 5. After the selective growth of the burying regions, 16 and 18, these continuous three regions, the active mesa 5 and two burying regions, 16 and 18, show a planar top surface, FIG. 3C. Two burying regions, 16 and 18, are made of semi-insulating InP doped with iron (Fe) and have the trap density for the electron of about 5×10¹⁶ cm⁻³.

Subsequently, the process etches one of burying regions 18 in a portion opposite to that in contact with the active mesa 5, FIG. 3D, to form the burying region 18a in a final shape. Thus, the active mesa 5 is put between the burying regions, 16 and 18a.

Next, the process forms the conductive region 20 so as to bury a space formed by the etching of the burying region 18. This conductive region is made of InP and shows a top surface continuous in flat to those of the active mesa 5 and two burying regions, 16 and 18a, FIG. 3E. On the planar surface of the conductive region 20, the active mesa 5, and two burying regions, 16 and 18a, are formed with a cladding region 22 made of an n-type InP, FIG. 3F.

After the grown the n-type InP cladding region 22, the process etches a portion of the InP substrate 2 and the InP cladding layer 4 until the surface 23b of the burying region 18a exposes, FIG. 7G, which resultantly forms two semiconductor regions, 3a and 3b, with a mesa shape each including the InP substrate 2 and the InP cladding layer 4, FIG. 3G. On the mesa of the semiconductor regions, 3a and 3b, are formed with electrodes, 26a and 26b, respectively, while, on the surface of the cladding region 22 is formed with metal film, FIG. 3H.

Thus, the LD 1 of the present embodiment has completed. The etching conditions to form the active mesa 5, FIG. 3B, and that for the burying region 18 may control the width of the burying region 16 and that of the other burying region 18a. Further, the etching condition to form two mesas of the semiconductor regions, 3a and 3b, may control the width of the electrode 26a.

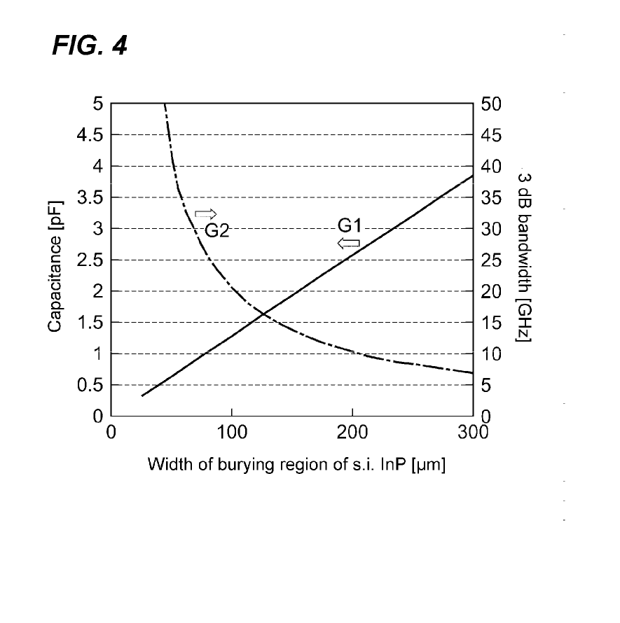

Next, some numerical analyses will be explained for the parasitic capacitor of the LD 1. The parasitic capacitor of the device 1 includes a capacitor inherently formed in a region containing two burying regions, 16 and 18a. FIG. 4 illustrates the capacitance of this parasitic capacitor with respect to a width of one of the burying region 16 that corresponds to the length D1 appeared in FIG. 2A. The behavior G1 in FIG. 4 shows this parasitic capacitance estimated by assuming that the parameters of the burying region are 12.1, 300 μm and 2.5 μm for the effective dielectric constant, a length along the direction x in FIG. 1 and a thickness, respectively.

FIG. 4 also illustrates a relation between the width of the burying region 16 and the 3 dB bandwidth f_{3 dB} [GHz] in the behavior G2, which is evaluated from an equation of:

f_{3 dB}=1/(2πCR),

where C is the parasitic capacitance due to the burying region explained above and R is the parasitic resistance of the active mesa 5, which is assumed to be connected in parallel to the parasitic capacitance and to have the resistance of 6Ω. According to FIG. 4, the width of the burying region smaller than 50 μm results in the parasitic capacitance less than 1 pF and the 3 dB bandwidth becomes 40 GHz or more.

Thus, the LD 1 according to the present embodiment shows the parasitic capacitance equal to or less than 1 pF, which enhances the high frequency performance of the LD 1. Further, the LD 1 of the invention may be mounted on the sub-mount 30 in the epi-down arrangement, which increases the heat dissipating efficiency.

While the preferred embodiments of the present invention have been described in detail above, many changes to these embodiments may be made without departing from the true scope and teachings of the present invention. The present invention, therefore, is limited only as claimed below and the equivalents thereof.

What is claimed is:

1. A semiconductor laser diode mounted on a sub-mount, comprising:
a first cladding layer coming in contact with said sub-mount;
a current confinement region provided on said first cladding layer, said current confinement region including an active mesa and first and second burying regions provided in both sides of said active mesa;
a conductive region provided in contiguity with said current confinement region on said first cladding layer and;
a first semiconductor region with a first electrode on a top surface thereof, said first semiconductor region being provided on said active mesa and said first burying region; and
a second semiconductor region with a second electrode on a top surface thereof, said second semiconductor region being provide on said second burying region and said conductive region,
wherein said first and second semiconductor regions are physically isolated to each other, and
wherein said first and second burying regions are semi-insulating characteristic.

2. The laser diode according to claim 1,
wherein said active mesa includes an active layer and a tunnel junction, and
wherein said first and second semiconductor substrates, said conductive region, and said first and second semiconductor regions have a same conducting type.

3. The laser diode according to claim 1,
wherein said first semiconductor region includes a second cladding layer and a first semiconductor substrate, said second cladding layer being provided on said first burying region and said active mesa, said first semiconductor substrate being provided on said second cladding layer and providing said first electrode thereon.

4. The laser diode according to claim 3,
wherein said second semiconductor region includes a third cladding layer and a second semiconductor substrate, said third cladding layer being provided on said second burying region and said conductive region, said second semiconductor substrate being provided on said third cladding layer and providing said second electrode thereon.

5. The laser diode according to claim 4,
wherein said second cladding layer and said third cladding layer have substantially same thickness and same doping concentration.

6. The laser diode according to claim 1,
wherein said first and second semiconductor regions are physically isolated to each other by a groove reaching a top surface of said second burying region.

7. The laser diode according to claim 1,
wherein said laser diode is mounted on said sub-mount through a metal film.

8. A method to produce an assembly of a semiconductor laser diode on a sub-mount, comprising steps of:
growing a stack of semiconductor layers epitaxially on a semiconductor substrate, said semiconductor layers including an active layer;
etching said stack to form an active mesa including said active layer;
burying said active mesa by selectively growing a semi-insulating semiconductor layer on both sides of said active mesa to form a current confinement structure;
forming a conductive region by etching a portion of said burying layer and burying said portion with said conductive region; and
etching a portion of said substrate to expose a surface of said burying region to form a pair of semiconductor regions physically isolated to each other.

9. The method according to claim 8,
wherein said step to grow said stack includes processes to grow a cladding layer, a tunnel junction, a separated confinement hetero-structure layer, said active layer, another separated and confinement hetero-structure layer.

10. The method according to claim 9,
further comprising a step, after etching said portion of said substrate, to mount said stack of said semiconductor layers on said sub-mount such that said cladding layer faces and comes in contact with said sub-mount.
